(19) United States
(12) Patent Application Publication
(10) Pub. No.: US 2026/0186082 A1
(43) Pub. Date: Jul. 2, 2026

(54) MAGNETORESISTIVE ELEMENT AND MAGNETIC SENSOR

(71) Applicant: TDK CORPORATION, Tokyo (JP)

(72) Inventors: Junichi OZEKI, Tokyo (JP); Norikazu OTA, Tokyo (JP); Hiraku HIRABAYASHI, Tokyo (JP)

(73) Assignee: TDK CORPORATION, Tokyo (JP)

(21) Appl. No.: 19/416,158

(22) Filed: Dec. 11, 2025

(30) Foreign Application Priority Data
Dec. 26, 2024 (JP) 2024-229790

(51) Int. Cl. G01R 33/09

(52) U.S. Cl. CPC G01R 33/09

(57) ABSTRACT

An MR element includes a magnetization pinned layer, a free layer configured to be able to have a magnetic vortex structure and so that a center of the magnetic vortex structure can move in accordance with a target magnetic field, and a gap layer arranged between the magnetization pinned layer and the free layer. The free layer includes a lower surface located at one end in a stacking direction of the magnetization pinned layer, the gap layer and the free layer, an upper surface located at the other end in the stacking direction, and a side surface connecting the lower surface and the upper surface. A side surface includes an inclined portion inclined relative to the stacking direction.

### CROSS REFERENCE TO RELATED APPLICATIONS

This application claims the benefit of Japanese Priority Patent Application No. 2024-229790 filed on December 26, 2024, the entire contents of which are incorporated herein by reference.

### BACKGROUND

The disclosure relates to a magnetoresistive element including a free layer configured to be able to have a magnetic vortex structure and a magnetic sensor including such magnetoresistive elements.

In recent years, magnetic sensors have been used for a variety of applications. Examples of known magnetic sensors include one that uses a spin-valve magnetoresistive element provided on a substrate. The spin-valve magnetoresistive element includes a magnetization pinned layer having a magnetization whose direction is fixed, a free layer having a magnetization whose direction is variable according to the direction of a target magnetic field, and a gap layer located between the magnetization pinned layer and the free layer.

U.S. Patent Application Publication No. 2023/0324477 discloses a magnetic sensor device including a plurality of tunneling magnetoresistance (TMR) elements. The TMR elements each include a free layer having a disk-like structure. A magnetization pattern having a closed magnetic flux, which is also referred to as a vortex state, is spontaneously formed in the free layer. In a magnetoresistive element including a free layer having a magnetic vortex structure as described in U.S. Patent Application Publication No. 2023/0324477, the center of the magnetic vortex structure moves in accordance with a magnetic field being a detection target, whereby the resistance value of the magnetoresistive element changes.

In a magnetic sensor using magnetoresistive elements, it is preferable that the resistance value of each magnetoresistive element change linearly or approximately linearly with respect to change of an applied magnetic field, in other words, the resistance value of the magnetoresistive element have good linearity. In a magnetoresistive element including a free layer having a magnetic vortex structure, as the magnetoresistive element in U.S. Patent Application Publication No. 2023/0324477, the magnitude of the magnetization of the entire free layer changes approximately linearly with respect to change of an applied magnetic field. Hence, it is possible to improve the linearity of the resistance value of the magnetoresistive element by using such a magnetoresistive element including a free layer having a magnetic vortex structure. In this magnetoresistive element, to further improve the linearity of the resistance value, it is necessary to improve the linearity itself of the magnitude of the magnetization of the entire free layer.

To increase the sensitivity of a magnetic sensor, it is necessary to increase the sensitivity of magnetoresistive elements. In a magnetoresistive element including a free layer having a magnetic vortex structure, by configuring the free layer so that the magnitude of the magnetization of the entire free layer significantly changes with respect to change of an applied magnetic field, the sensitivity of the magnetoresistive element can be increased. However, sufficient studies have not been performed heretofore about an approach for improving both linearity and sensitivity by a simple configuration in a magnetoresistive element including a free layer having a magnetic vortex structure.

### SUMMARY

A magnetoresistive element according to one embodiment of the disclosure includes a magnetization pinned layer having a magnetization whose direction is fixed, a free layer configured to be able to have a magnetic vortex structure and so that a center of the magnetic vortex structure can move in accordance with a target magnetic field, and a gap layer arranged between the magnetization pinned layer and the free layer. The free layer includes a first lower surface located at one end in a stacking direction of the magnetization pinned layer, the gap layer and the free layer, a first upper surface located at the other end in the stacking direction, and a first side surface connecting the first lower surface and the first upper surface. The first side surface includes an inclined portion inclined relative to the stacking direction.

A magnetic sensor according to one embodiment of the disclosure is a magnetic sensor including a plurality of magnetic detection elements. Each of the plurality of magnetic detection elements is a magnetoresistive element according to one embodiment of the disclosure.

Objects, features, and advantages of the disclosure appear more fully from the following description.

### BRIEF DESCRIPTION OF THE DRAWINGS

The accompanying drawings are included to provide an understanding of the disclosure and are incorporated in and constitute a part of this specification. The drawings illustrate example embodiments and, together with the specification, serve to explain the principles of the technology.

FIG. 1 is a plan view showing a magnetic sensor according to a first example embodiment of the disclosure.

FIG. 2 is a circuit diagram showing a circuit configuration of the magnetic sensor according to the first example embodiment of the disclosure.

FIG. 3 is a plan view showing a part of the magnetic sensor according to the first example embodiment of the disclosure.

FIG. 4 is a perspective view showing a magnetoresistive element in the first example embodiment of the disclosure.

FIG. 5 is a plan view showing a free layer of the magnetoresistive element in the first example embodiment of the disclosure.

FIG. 6 is an explanatory view showing the direction of a magnetization of the free layer of the magnetoresistive element in the first example embodiment of the disclosure.

FIG. 7 is an explanatory view showing the direction of a magnetization of the free layer when a target magnetic field is applied to the magnetoresistive element in the first example embodiment of the disclosure.

FIG. 8 is an explanatory view showing the direction of a magnetization of the free layer when the target magnetic field is applied to the magnetoresistive element in the first example embodiment of the disclosure.

FIG. 9 is a side view showing the free layer and a magnetization pinned layer of the magnetoresistive element in the first example embodiment of the disclosure.

FIG. 10 is an explanatory diagram showing a relationship between the strength of a magnetic field component and the magnitude of a magnetization of the entire free layer in the first example embodiment of the disclosure.

FIG. 11 is a characteristic chart showing the relationship between the strength of the magnetic field component and the magnitude of the magnetization of the entire free layer determined by a first simulation.

FIG. 12 is a characteristic chart showing a relationship between an inclination angle and slope determined by the first simulation.

FIG. 13 is a characteristic chart showing a relationship between an inclination angle and linearity determined by the first simulation.

FIG. 14 is a characteristic chart showing a relationship between an inclination angle and the strength of a magnetic field component at which a magnetic vortex structure disappears and a relationship between an inclination angle and the strength of the magnetic field component at which a magnetic vortex structure is generated, determined by the first simulation.

FIG. 15 is a characteristic chart showing a relationship between the strength of a magnetic field component and linearity determined by a second simulation.

FIG. 16 is a side view showing a magnetoresistive element in a second example embodiment of the disclosure.

FIG. 17 is a side view showing a free layer and a magnetization pinned layer of the magnetoresistive element in the second example embodiment of the disclosure.

FIG. 18 is a characteristic chart showing a relationship between the strength of the magnetic field component and the magnitude of a magnetization of the entire free layer determined by a third simulation.

FIG. 19 is a characteristic chart showing a relationship between the strength of the magnetic field component and the magnitude of the magnetization of the entire free layer determined by the third simulation.

FIG. 20 is a characteristic chart showing a relationship between an inclination angle and slope determined by the third simulation.

FIG. 21 is a characteristic chart showing a relationship between an inclination angle and linearity determined by the third simulation.

FIG. 22 is a side view showing a magnetoresistive element in a third example embodiment of the disclosure.

FIG. 23 is a side view showing a free layer and a magnetization pinned layer of the magnetoresistive element in the third example embodiment of the disclosure.

FIG. 24 is a characteristic chart showing a relationship between the strength of a magnetic field component and the magnitude of a magnetization of the entire free layer determined by a fourth simulation.

FIG. 25 is a characteristic chart showing a relationship between the strength of the magnetic field component and the magnitude of the magnetization of the entire free layer determined by the fourth simulation.

FIG. 26 is a characteristic chart showing a relationship between an inclination angle and slope determined by the fourth simulation.

FIG. 27 is a characteristic chart showing a relationship between an inclination angle and linearity determined by the fourth simulation.

### DETAILED DESCRIPTION

An object of the disclosure is to provide a magnetoresistive element including a free layer having a magnetic vortex structure, the magnetoresistive element being able to improve linearity and sensitivity by a simple configuration, and a magnetic sensor including such magnetoresistive elements.

In the following, some example embodiments and modification examples of the disclosure are described in detail with reference to the accompanying drawings. Note that the following description is directed to illustrative examples of the disclosure and not to be construed as limiting the technology. Elements including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Similar elements are denoted with the same reference numerals to avoid redundant descriptions.

### First Example Embodiment

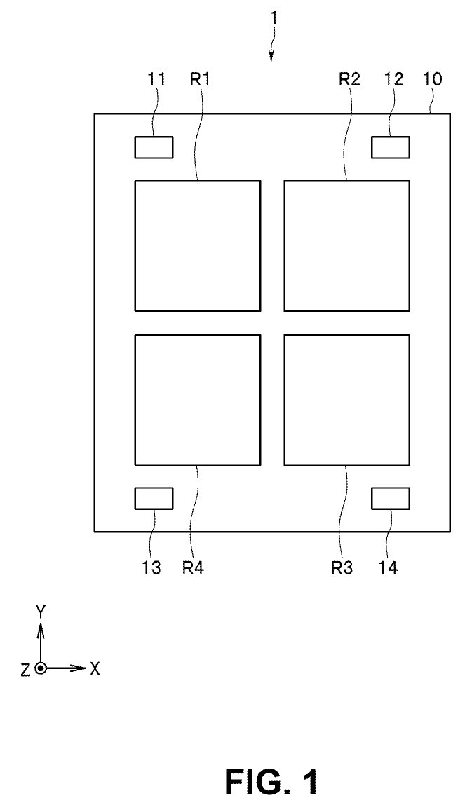

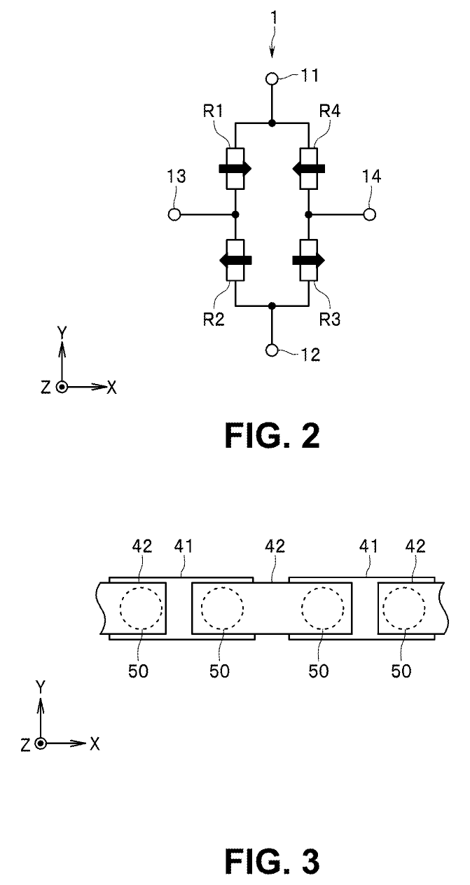

First, with reference to FIG. 1 and FIG. 2, a schematic configuration of a magnetic sensor according to a first example embodiment of the disclosure is described. FIG. 1 is a plan view showing a magnetic sensor 1 according to the example embodiment. FIG. 2 is a circuit diagram showing a circuit configuration of the magnetic sensor 1 according to the example embodiment.

The magnetic sensor 1 according to the example embodiment includes a power supply terminal 11, a ground terminal 12, a first output terminal 13, a second output terminal 14, a first resistor section R1, a second resistor section R2, a third resistor section R3, a fourth resistor section R4, and a substrate 10. The first to fourth resistor sections R1 to R4, the power supply terminal 11, the ground terminal 12, and the first and second output terminals 13 and 14 are provided on the substrate 10.

Each of the first to fourth resistor sections R1 to R4 includes a plurality of magnetic detection elements and is configured to detect a target magnetic field to generate at least one detection signal. In the example embodiment, in particular, the plurality of magnetic detection elements are a plurality of magnetoresistive elements. The magnetoresistive elements will be referred to as MR elements below. Since each of the first to fourth resistor sections R1 to R4 includes a plurality of MR elements, it can be said that the magnetic sensor 1 includes a plurality of MR elements.

As shown in FIG. 2, the first resistor section R1 is provided between the power supply terminal 11 and the first output terminal 13 in the circuit configuration. The second resistor section R2 is provided between the ground terminal 12 and the first output terminal 13 in the circuit configuration. The third resistor section R3 is provided between the ground terminal 12 and the second output terminal 14 in the circuit configuration. The fourth resistor section R4 is provided between the power supply terminal 11 and the second output terminal 14 in the circuit configuration. Note that, in the application, the expression "in the (a) circuit configuration" is used to indicate a layout in a circuit diagram, not a layout in a physical configuration.

A voltage or an electric current having a specific magnitude is applied to the power supply terminal 11. The ground terminal 12 is connected to the ground.

Here, as shown in FIG. 1, an X direction, a Y direction, and a Z direction are defined. The X direction, the Y direction, and the Z direction are orthogonal to one another. The opposite directions to the X, Y, and Z directions will be expressed as −X, −Y, and −Z directions, respectively. In the example embodiment, in particular, a direction perpendicular to the surface of the substrate 10 is referred to as the Z direction.

As used herein, the term "above" refers to positions located ahead a certain reference position in the Z direction, and "below" refers to positions opposite from the "above" positions with respect to the certain reference position. For each component of the magnetic sensor 1, a surface located at an end in the Z direction is referred to as an "upper surface", and a surface located at an end in the −Z direction is referred to as a "lower surface". The expression "when viewed in a specific direction (e.g., the Z direction)" means that an object is viewed from a position away in the specific direction or in one direction parallel to the specific direction, in other words, an object is viewed in a planar view.

FIG. 1 shows an example of the layout of the first to fourth resistor sections R1 to R4. In this example, the first and second resistor sections R1 and R2 are arranged in a direction parallel to the X direction. The second resistor section R2 is arranged forward of the first resistor section R1 in the X direction.

The third and fourth resistor sections R3 and R4 are arranged in the direction parallel to the X direction. The fourth resistor section R4 is arranged forward of the third resistor section R3 in the −X direction. The third resistor section R3 is arranged forward of the second resistor section R2 in the −Y direction. The fourth resistor section R4 is arranged forward of the first resistor section R1 in the −Y direction.

Note that the layout of the first to fourth resistor sections R1 to R4 is not limited to the example shown in FIG. 1. For example, the first to fourth resistor sections R1 to R4 may be arranged in a specific order in the direction parallel to the X direction or in a direction parallel to the Y direction.

Next, a concrete configuration of the magnetic sensor 1 will be described in detail with reference to FIG. 3. FIG. 3 is a plan view showing a part of the magnetic sensor 1.

The magnetic sensor 1 in the example embodiment includes a plurality of MR elements 50 and a plurality of lower electrodes 41 and a plurality of upper electrodes 42 for electrically connecting the plurality of MR elements 50. The plurality of lower electrodes 41 are arranged on the substrate 10 (refer to FIG. 1). The plurality of MR elements 50 are arranged on the plurality of lower electrodes 41. The plurality of upper electrodes 42 are arranged over the plurality of MR elements 50.

The plurality of MR elements 50 may be connected in series to each other by the plurality of lower electrodes 41 and the plurality of upper electrodes 42. In this case, a method of connecting the plurality of MR elements 50 is as follows. As shown in FIG. 3, each of the lower electrodes 41 has an elongated shape. Every two lower electrodes 41 that are adjacent to each other in the longitudinal direction of the lower electrodes 41 have a gap therebetween. Each MR element 50 is arranged in the vicinity of each of both longitudinal ends on the upper surface of the corresponding lower electrode 41. Each upper electrode 42 has an elongated shape, and electrically connects the two adjacent MR elements 50 arranged on two lower electrodes 41 that are adjacent to each other in the longitudinal direction of the lower electrodes 41. In such a manner, the plurality of MR elements 50 are connected in series.

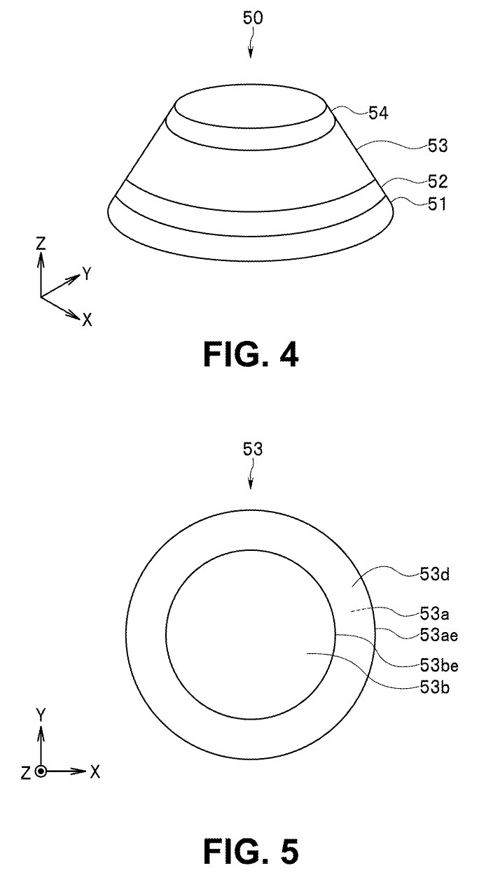

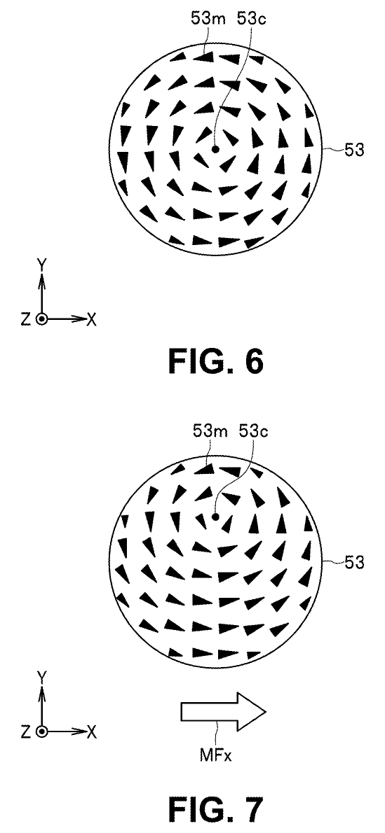

Next, a configuration of the MR element 50 will be described with reference to FIG. 4 to FIG. 6. FIG. 4 is a perspective view showing the MR element 50. FIG. 5 is a plan view showing the free layer of the MR element 50. FIG. 6 is an explanatory view showing the direction of a magnetization of the free layer of the MR element 50.

The MR element 50 includes a magnetization pinned layer 51 having a magnetization 51m whose direction is fixed, a free layer 53, a gap layer 52 arranged between the magnetization pinned layer 51 and the free layer 53, and a cap layer 54 arranged on the free layer 53. The material and shape of the free layer 53 are selected so as to have a magnetic vortex structure (also referred to as a vortex state). The gap layer 52 is a tunnel barrier layer or a nonmagnetic conductive layer. The cap layer 54 is formed of a nonmagnetic metallic material such as Ta or Ru, for example.

At least a part of the free layer 53 has a truncated cone shape or a substantially truncated cone shape. In the example shown in FIG. 4, the entire free layer 53 has a truncated cone shape, and also the entire MR element 50 has a truncated cone shape.

As shown in FIG. 5, the free layer 53 includes a lower surface 53a and an upper surface 53b located at respective both ends in a stacking direction of the magnetization pinned layer 51, the gap layer 52, and the free layer 53, and a side surface 53d connecting the lower surface 53a and the upper surface 53b. The lower surface 53a is located at the end in the −Z direction of the free layer 53 and faces the gap layer 52. The upper surface 53b is located at the end in the Z direction of the free layer 53 and faces the cap layer 54.

At least a part of the side surface 53d is inclined relative to a direction parallel to the stacking direction, i.e., the Z direction. The side surface 53d may be a plane or a curved surface. The planar shape of the side surface 53d when viewed in one direction parallel to the stacking direction, i.e., the Z direction, may be an annular shape. The planar shape (shape viewed in the Z direction) of each of the lower surface 53a and the upper surface 53b is circular. The planar shape of the upper surface 53b is smaller than the planar shape of the lower surface 53a. In FIG. 5, a reference sign 53ae indicates an outer edge of the lower surface 53a when viewed in the Z direction, and a reference sign 53be indicates an outer edge of the upper surface 53b when viewed in the Z direction. When viewed in the stacking direction (Z direction), the outer edge 53be of the upper surface 53b is located on the inner side of the outer edge 53ae of the lower surface 53a.

FIG. 6 shows the direction of a magnetization of the free layer 53 at any cross-section parallel to a plane (XY plane) orthogonal to the stacking direction. The free layer 53 has a magnetization 53m that forms a vortex pattern centered around a magnetic vortex structure center 53c. When there is no magnetic field applied to the MR element 50, the magnetic vortex structure center 53c matches with or substantially matches with the axis of the truncated cone. The free layer 53 is configured so that the magnetic vortex structure center 53c can move in accordance with a target magnetic field MF.

The magnetic vortex structure center 53c moves when a component in a direction orthogonal to the Z direction of the target magnetic field MF is applied to the free layer 53. The free layer 53 is preferably not saturated within the range of variations in the strength of the component.

In the example embodiment, the magnetization 51m of the magnetization pinned layer 51 includes a component in the direction parallel to the X direction. Note that, when the magnetization 51m of the magnetization pinned layer 51 includes a component in a specific direction, the component in the specific direction may be the main component of the magnetization 51m of the magnetization pinned layer 51. In the example embodiment, when the magnetization 51m of the magnetization pinned layer 51 includes the component in the specific direction, the direction of the magnetization 51m of the magnetization pinned layer 51 is the same or substantially the same as the specific direction.

The MR element 50 may further include an antiferromagnetic layer. The antiferromagnetic layer is formed of an antiferromagnetic material, and is in exchange coupling with the magnetization pinned layer 51 to thereby fix the direction of the magnetization 51m of the magnetization pinned layer 51. Alternatively, the magnetization pinned layer 51 may be a so-called self-pinned layer (Synthetic Ferri Pinned layer, SFP layer). The self-pinned layer has a stacked ferri structure in which a ferromagnetic layer, a nonmagnetic intermediate layer, and a ferromagnetic layer are stacked, and the two ferromagnetic layers are antiferromagnetically coupled.

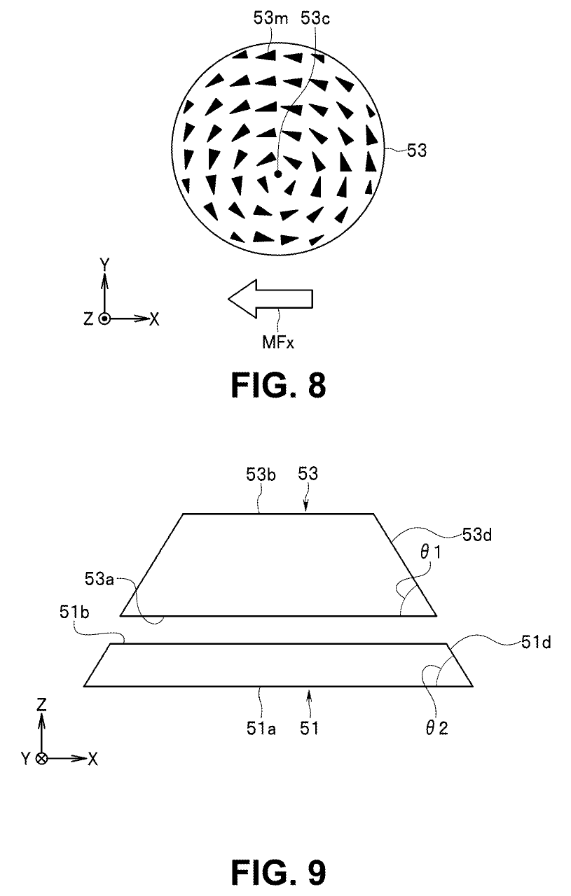

Here, the resistance value of the MR element 50 is described while focusing on a case in which the direction of the magnetization 51m of the magnetization pinned layer 51 is the −X direction, as an example. FIG. 7 and FIG. 8 show the free layer 53 when a magnetic field component MFx, which is in a direction parallel to the X direction, of the target magnetic field MF is applied to the free layer 53.

FIG. 7 shows the free layer 53 when the direction of the magnetic field component MFx is the X direction. In such a case, the magnetic vortex structure center 53c moves due to the magnetic field component MFx, and the amount of the magnetization 53m oriented in the X direction is greater than that of the magnetization 53m oriented in the −X direction. In this case, the resistance value of the MR element 50 is increased.

FIG. 8 shows the free layer 53 when the direction of the magnetic field component MFx is the −X direction. In such a case, the magnetic vortex structure center 53c moves due to the magnetic field component MFx, and the amount of the magnetization 53m oriented in the −X direction is greater than that of the magnetization 53m oriented in the X direction. In this case, the resistance value of the MR element 50 is reduced.

A change amount of the resistance value of the MR element 50 depends on the strength of the magnetic field component MFx. In a case in which the direction of the magnetic field component MFx is the X direction, when the strength of the magnetic field component MFx is increased, the amount of the magnetization 53m oriented in the X direction is increased. The resistance value of the MR element 50 is increased as the amount of the magnetization 53m oriented in the X direction is increased. In a case in which the direction of the magnetic field component MFx is the −X direction, when the strength of the magnetic field component MFx is increased, the amount of the magnetization 53m oriented in the −X direction is increased. The resistance value of the MR element 50 is reduced as the amount of the magnetization 53m oriented in the −X direction is increased. As the strength of the magnetic field component MFx is increased, the resistance value of the MR element 50 changes so that an increase amount or a reduction amount thereof is increased. As the strength of the magnetic field component MFx is reduced, the resistance value of the MR element 50 changes so that an increase amount or a reduction amount thereof is reduced. In the example embodiment, in particular, a relationship between strength Hx of the magnetic field component MFx and the resistance value of the MR element 50 is a linear relationship or a substantially linear relationship as long as a condition where the free layer 53 is not saturated is satisfied.

Next, with reference to FIG. 2, the direction of the magnetization 51m of the magnetization pinned layer 51 in each of the first resistor section R1 to the fourth resistor section R4 is described. The magnetization 51m of the magnetization pinned layer 51 of each of the plurality of MR elements 50 in the first resistor section R1 includes a component in a first magnetization direction. The magnetization 51m of the magnetization pinned layer 51 of each of the plurality of MR elements 50 in the second resistor section R2 includes a component in a second magnetization direction opposite to the first magnetization direction. The magnetization 51m of the magnetization pinned layer 51 of each of the plurality of MR elements 50 in the third resistor section R3 includes a component in the first magnetization direction. The magnetization 51m of the magnetization pinned layer 51 of each of the plurality of MR elements 50 in the fourth resistor section R4 includes a component in the second magnetization direction. In FIG. 2, the two arrows that are illustrated in the first resistor section R1 and the third resistor section R3 represent the first magnetization direction. In FIG. 2, the two arrows that are illustrated in the second resistor section R2 and the fourth resistor section R4 represent the second magnetization direction. In the example embodiment, in particular, the first magnetization direction is the X direction, and the second magnetization direction is the −X direction.

Next, with reference to FIG. 2, at least one detection signal generated by the magnetic sensor 1 is described. When the direction of the magnetic field component MFx is the X direction, the resistance value of each of the plurality of MR elements 50 of the first resistor section R1 and the third resistor section R3 is reduced, and the resistance value of each of the plurality of MR elements 50 of the second resistor section R2 and the fourth resistor section R4 is increased, as compared to a state in which there is no magnetic field component MFx. As a result, the resistance value of each of the first resistor section R1 and the third resistor section R3 is reduced, and the resistance value of each of the second resistor section R2 and the fourth resistor section R4 is increased.

When the direction of the magnetic field component MFx is the −X direction, the change in the resistance value of each of the first resistor section R1 to the fourth resistor section R4 is opposite to that in the above-described case in which the direction of the magnetic field component MFx is the X direction.

As described above, when the direction and the strength of the magnetic field component MFx change, the resistance value of each of the first resistor section R1 to the fourth resistor section R4 changes so that the resistance value of each of the first resistor section R1 and the third resistor section R3 is increased while the resistance value of each of the second resistor section R2 and the fourth resistor section R4 is reduced, or the resistance value of each of the first resistor section R1 and the third resistor section R3 is reduced while the resistance value of each of the second resistor section R2 and the fourth resistor section R4 is increased. With this, a potential of a connection point between the first resistor section R1 and the second resistor section R2, in other words, a potential of the first output terminal 13, and a potential of a connection point between the third resistor section R3 and the fourth resistor section R4, in other words, a potential of the second output terminal 14 change. The magnetic sensor 1 may generate a signal corresponding to the potential of the first output terminal 13 and a signal corresponding to the potential of the second output terminal 14, as detection signals. Alternatively, the magnetic sensor 1 may generate a signal corresponding to a potential difference between the first output terminal 13 and the second output terminal 14, as a detection signal. In this case, the magnetic sensor 1 may further include a differential amplifier (differential detector) that outputs the signal corresponding to the potential difference between the first output terminal 13 and the second output terminal 14, as the detection signal.

Next, the shape of the side surface 53d of the free layer 53 and the shape of the side surface of the magnetization pinned layer 51 will be described with reference to FIG. 9. FIG. 9 is a side view showing the free layer 53 and the magnetization pinned layer 51 of the MR element 50. The side surface 53d of the free layer 53 includes an inclined portion inclined relative to the direction parallel to the stacking direction, i.e., the Z direction. In the example shown in FIG. 9, the entire side surface 53d is an inclined portion. In the example shown in FIG. 9, the entire side surface 53d (inclined portion) is a plane. However, at least a part of the side surface 53d (inclined portion) may be a curved surface. The side surface 53d of the free layer 53 may include a portion parallel to or substantially parallel to the Z direction, in addition to the inclined portion.

In FIG. 9, a sign θ1 indicates the angle of the inclined portion of the side surface 53d with respect to the lower surface 53a of the free layer 53. The angle θ1 will be referred to as an inclination angle of the side surface 53d below.

At least a part of the magnetization pinned layer 51 has a truncated cone shape or a substantially truncated cone shape. The magnetization pinned layer 51 includes a lower surface 51a and an upper surface 51b located at respective both ends in the direction parallel to the stacking direction, i.e., the Z direction, and a side surface 51d connecting the lower surface 51a and the upper surface 51b. The lower surface 51a is located at the end in the −Z direction of the magnetization pinned layer 51. The upper surface 51b is located at the end in the Z direction of the magnetization pinned layer 51 and faces the gap layer 52.

The side surface 51d includes an inclined portion inclined relative to the direction parallel to the Z direction. In the example shown in FIG. 9, the entire side surface 51d is an inclined portion. In FIG. 9, a sign θ2 indicates the angle of the inclined portion of the side surface 51d with respect to the lower surface 51a of the magnetization pinned layer 51. The angle θ2 will be referred to as an inclination angle of the side surface 51d below. The inclination angle θ2 of the side surface 51d may match with or need not match with the inclination angle θ1 of the side surface 53d. In the example shown in FIG. 9, the inclination angle θ2 of the side surface 51d may match with or substantially match with the inclination angle θ1 of the side surface 51d.

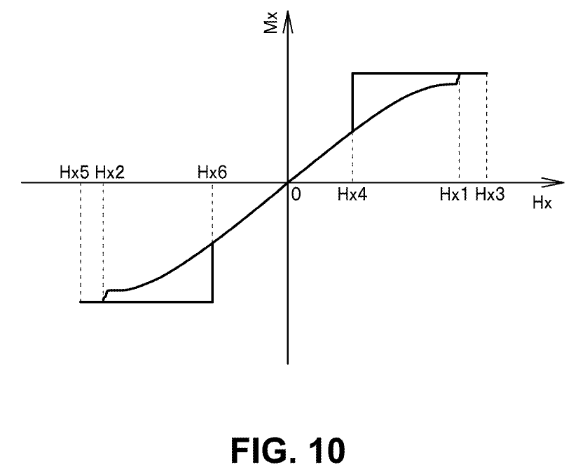

Next, with reference to FIG. 10, a relationship between the strength of the magnetic field component MFx and the magnitude of the magnetization of the entire free layer 53 will be described. FIG. 10 is an explanatory view schematically showing the relationship between the strength of the magnetic field component MFx and the magnitude of the magnetization of the entire free layer 53. In FIG. 10, the horizontal axis indicates the strength Hx of the magnetic field component MFx, and the vertical axis indicates the magnitude Mx of the magnetization of the entire free layer 53. In FIG. 10, the strength Hx when the direction of the magnetic field component MFx is the X direction is expressed by a positive value, and the strength Hx when the direction of the magnetic field component MFx is the −X direction is expressed by a negative value. If the direction of the magnetic field component MFx is the X direction, the magnitude Mx of the magnetization of the entire free layer 53 increases as the amount of the magnetization 53m oriented in the X direction increases. If the direction of the magnetic field component MFx is the −X direction, the magnitude Mx of the magnetization of the entire free layer 53 decreases as the amount of the magnetization 53m oriented in the −X direction increases.

First, description is made on a case in which the strength Hx is increased from 0. When the strength Hx is gradually increased from 0, the magnetization magnitude Mx is gradually increased. When the strength Hx is equal to or greater than a value Hx1, the magnetization magnitude Mx is constant, and the free layer 53 is magnetically saturated.

Next, description is made on a case in which the strength Hx is reduced from 0. When the strength Hx is gradually reduced from 0, the magnetization magnitude Mx is also gradually reduced. When the strength Hx is equal to or less than a value Hx2, the magnetization magnitude Mx is constant, and the free layer 53 is magnetically saturated.

As shown in FIG. 10, within a specific range where the strength Hx is greater than the value Hx2, and is less than the value Hx1, the magnetization magnitude Mx changes linearly with respect to the change of the strength Hx. Note that the expression "to linearly change" indicates that the magnetization magnitude Mx changes linearly or substantially linearly with respect to the change of the strength Hx in the characteristic chart showing the relationship between the strength Hx and the magnetization magnitude Mx.

In the example embodiment, within the change range of the strength Hx, it is preferred that the free layer 53 be not magnetically saturated while the magnetization magnitude Mx linearly changes with respect to the change of the strength Hx.

Note that, when the strength Hx is greater than the value Hx1 and the free layer 53 is magnetically saturated, and thereafter the strength Hx is reduced from a value Hx3 greater than the value Hx1, there is less change in the magnetization magnitude Mx until the strength Hx reaches a value Hx4 less than the value Hx1. When the strength Hx is less than the value Hx4, the magnetization magnitude Mx linearly changes with respect to the change of the strength Hx similarly to a case in which the strength Hx changes within the specific range from the value Hx2 to the value Hx1.

Similarly, when the strength Hx is less than the value Hx2 and the free layer 53 is magnetically saturated, and thereafter the strength Hx is increased from a value Hx5 less than the value Hx2, there is less change in the magnetization magnitude Mx until the strength Hx reaches a value Hx6 greater than the value Hx2. When the strength Hx is greater than the value Hx6, the magnetization magnitude Mx linearly changes with respect to the change of the strength Hx similarly to a case in which the strength Hx changes within the specific range from the value Hx2 to the value Hx1.

Although not shown, the relationship between the strength Hx and the resistance value of the MR element 50 is similar to the relationship between the strength Hx and the magnitude of the magnetization of the free layer 53.

Next, results of first and second simulations for investigating influences of the inclination angle θ1 of the side surface 53d of the free layer 53 on the characteristics of the MR element 50 will be described. First, the first simulation will be described. In the first simulation, the inclination angle θ1 was changed within a range from 30° to 90° while the diameter of the lower surface 53a of the free layer 53 was maintained the same. In this state, the relationship between the strength Hx of the magnetic field component MFx and the magnitude Mx of the magnetization was determined for each value of the inclination angle θ1. In the first simulation, the diameter of the lower surface 53a of the free layer 53 was set at 500 nm. Note that, in a case where the inclination angle θ1 is 90°, the free layer 53 has a cylindrical or substantially cylindrical shape.

From the relationship between the strength Hx of the magnetic field component MFx and the magnitude Mx of the magnetization, the ratio of the change amount of the magnitude Mx of the magnetization to the change amount of the strength Hx of the magnetic field component MFx, i.e., slope, was determined. Slope was determined within a range of the strength Hx of the magnetic field component MFx at which the free layer 53 would not be magnetically saturated. The slope is a parameter corresponding to the sensitivity of the MR element 50. The larger the slope is, the higher the sensitivity of the MR element 50 becomes.

From the relationship between the strength Hx of the magnetic field component MFx and the magnitude Mx of the magnetization, linearity of the magnitude Mx of the magnetization was determined. The linearity is defined by using a characteristic curve representing the relationship between the strength Hx of the magnetic field component MFx and the magnitude Mx of the magnetization, and an approximate straight line of this characteristic curve. In other words, the linearity is a residual between a value on the approximate straight line and a value on the characteristic curve when the value of the strength Hx of the magnetic field component MFx is the same. The linearity was determined within a range of the strength Hx of the magnetic field component MFx at which the free layer 53 would not be magnetically saturated. It can be said that the smaller the value of the linearity is, the better the linearity becomes.

From the relationship between the strength Hx of the magnetic field component MFx and the magnitude Mx of the magnetization, strength Ha (corresponding to Hx1 in FIG. 10) of the magnetic field component MFx at which a magnetic vortex structure would disappear with an increase of the strength Hx of the magnetic field component MFx and strength Hn (corresponding to Hx4 in FIG. 10) of the magnetic field component MFx at which a magnetic vortex structure would be generated with a decrease of the strength Hx of the magnetic field component MFx after the free layer 53 is magnetically saturated are determined. The larger the strengths Ha and Hn of the magnetic field component MFx are, the larger the measurement range of the magnetic field component MFx becomes.

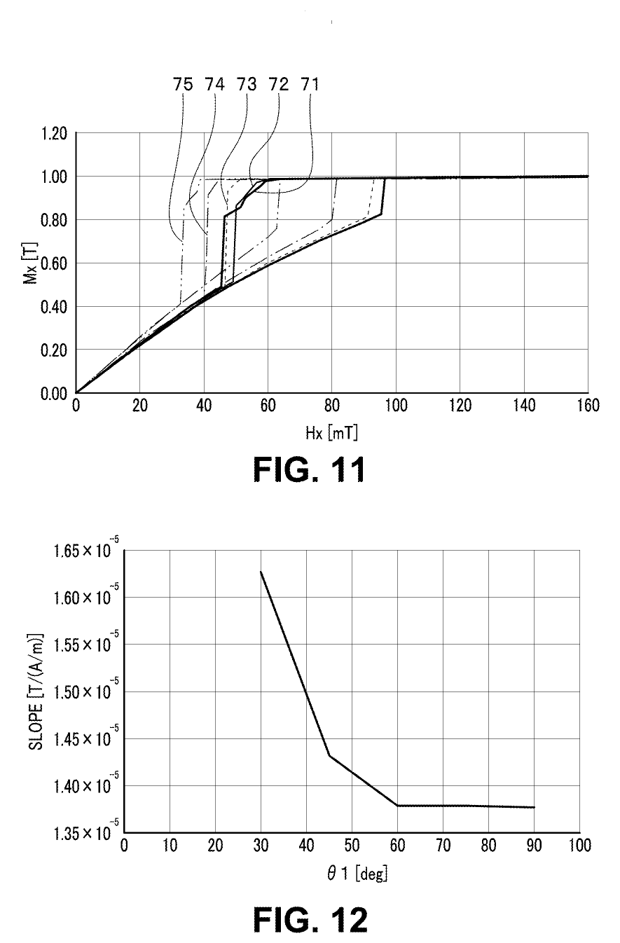

FIG. 11 is a characteristic chart showing a relationship between the strength Hx of the magnetic field component MFx and the magnitude Mx of the magnetization. In FIG. 11, the horizontal axis represents the strength Hx (unit being mT), and the vertical axis represents the magnitude Mx of the magnetization (unit being T). In FIG. 11, a reference numeral 71 indicates a case where the inclination angle θ1 is 90°, a reference numeral 72 indicates a case where the inclination angle θ1 is 75°, a reference numeral 73 indicates a case where the inclination angle θ1 is 60°, a reference numeral 74 indicates a case where the inclination angle θ1 is 45°, and a reference numeral 75 indicates a case where the inclination angle θ1 is 30°.

FIG. 12 is a characteristic chart showing a relationship between the inclination angle θ1 and the slope. In FIG. 12, the horizontal axis represents the inclination angle θ1, and the vertical axis represents the slope. Note that, in FIG. 12, the slope is determined as the ratio of the change amount (unit being T) of the magnitude Mx of the magnetization with respect to the change amount (unit being A/m) of the magnitude of the strength Hx. Specifically, the slope of an approximate straight line obtained by performing linear approximation on a characteristic curve representing the relationship between the strength Hx and the magnitude Mx of magnetization within a range where the magnitude of the strength Hx is 0 or larger and 4.8 x 10⁴ or smaller in each value of the inclination angle θ1 is determined. In FIG. 12, the slopes of respective values of the inclination angle θ1 are connected with a line. Note that, also in each of the drawings to be used in the description below, which are similar to FIG. 12, a manner of determining slope is the same as that in FIG. 12. As shown in FIG. 12, the smaller the inclination angle θ1 is, the larger the slope becomes.

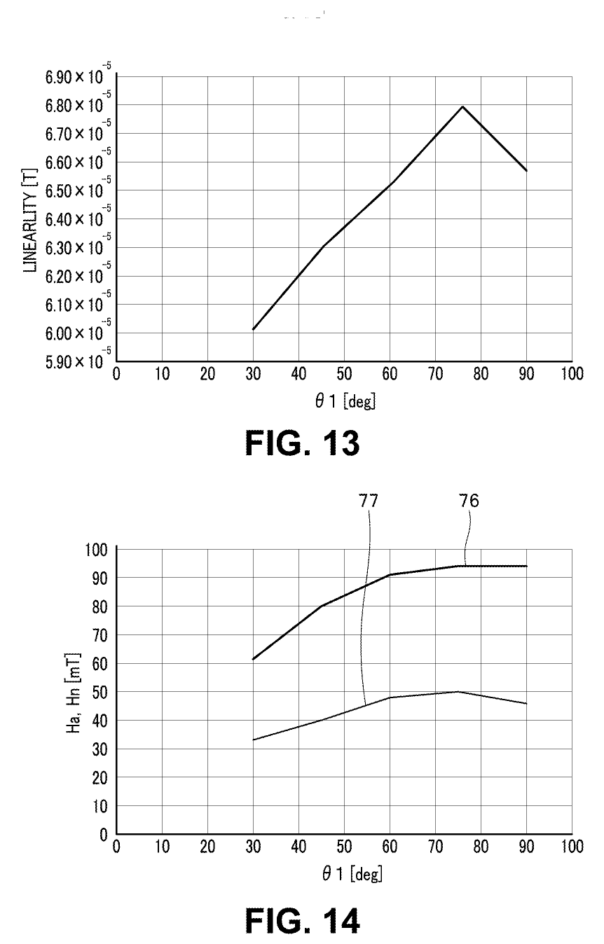

FIG. 13 is a characteristic chart showing a relationship between the inclination angle θ1 and linearity. In FIG. 13, the horizontal axis represents the inclination angle θ1, and the vertical axis represents the linearity. Note that, in FIG. 13, the unit of the linearity is T. In FIG. 13, the residue between a value on the approximate straight line and a value on the characteristic curve when the magnitude of the strength Hx is 4.8 x 10⁴ A/m is determined as linearity. In FIG. 13, the values of the linearity at the respective values of the inclination angle θ1 are connected with a line. Note that, also in each of the drawings to be used in the description below, which are similar to FIG. 13, a manner of determining linearity is the same as that in FIG. 13. As shown in FIG. 13, the smaller the inclination angle θ1 is, the smaller the value of the linearity becomes when the inclination angle θ1 is 75° or smaller.

FIG. 14 is a characteristic chart showing a relationship between the inclination angle θ1 and the strength Ha of the magnetic field component MFx at which a magnetic vortex structure disappears and a relationship between the inclination angle θ1 and the strength Hn of the magnetic field component MFx at which a magnetic vortex structure is generated. In FIG. 14, the horizontal axis represents the inclination angle θ1, and the vertical axis represents the strengths Ha and Hn (unit being mT). A reference numeral 76 indicates the strength Ha, and a reference numeral 77 indicates the strength Hn. As shown in FIG. 14, the smaller the inclination angle θ1 is, the smaller the strengths Ha and Hn become when the inclination angle θ1 is 75° or smaller.

As understood from the result of the first simulation, by reducing the inclination angle θ1, the slope increases while the value of the linearity decreases. In other words, according to the example embodiment, a simple configuration that the inclined portion is provided to the side surface 53d of the free layer 53 can improve both linearity and sensitivity.

According to the result of the first simulation, the inclination angle θ1 is preferably 60° or smaller. Meanwhile, as shown in FIG. 14, when the inclination angle θ1 decreases, the strengths Ha and Hn decrease. From a viewpoint of increasing the measurement range of the magnetic field component MFx to some extent, the inclination angle θ1 is preferably 30° or larger.

Next, the second simulation will be described. In the second simulation, a model of a practical example and a model of a comparative example were used. The model of the practical example is a model for the free layer 53 in the example embodiment. In the model of the practical example, the inclination angle θ1 was set at 45°. The model of the comparative example is a model for a free layer 53 of the comparative example with the inclination angle θ1 being 90°.

In the model of the practical example and the model of the comparative example, the diameter of the lower surface 53a of the free layer 53 of each of the model of the practical example and the model of the comparative example was designed so that the ratio of the change amount of the magnitude Mx of magnetization with respect to the change amount of the strength Hx of the magnetic field component MFx, i.e., the slope, would be the same in the model of the practical example and the model of the comparative example. In the model of the practical example, the diameter of the lower surface 53a of the free layer 53 was set at 500 nm. In the model of the comparative example, the diameter of the lower surface 53a of the free layer 53 was set at 530 nm.

In the second simulation, a relationship between the strength Hx of the magnetic field component MFx and the magnitude Mx of the magnetization was determined for each of the model of the practical example and the model of the comparative example. From the determined relationship, linearity of the magnitude Mx of the magnetization was determined. In the second simulation, in particular, the value of linearity was determined for each value of the strength Hx.

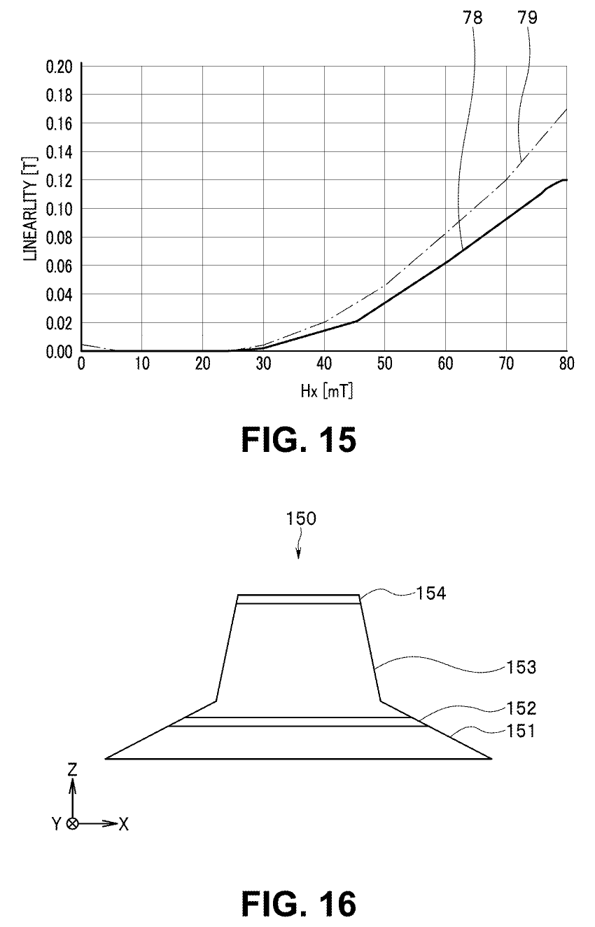

FIG. 15 is a characteristic chart showing the relationship between the strength Hx and the linearity. In FIG. 15, the horizontal axis represents the strength Hx (unit being mT), and the vertical axis represents the linearity (unit being T). A curve indicated with a reference numeral 78 represents the linearity of the model of the practical example. A curve indicated with a reference numeral 79 represents the linearity of the model of the comparative example. As shown in FIG. 15, the values of the linearity of the model of the practical example (reference numeral 78) are smaller than the values of the linearity of the model of the comparative example (reference numeral 79).

As understood from the second simulation, according to the example embodiment, by providing the inclined portion to the side surface 53d of the free layer 53, linearity can be improved.

Note that, although not shown, the strengths Ha and Hn were smaller in the model of the practical example than those of the model of the comparative example similarly to the first simulation. Hence, it is desirable to determine the inclination angle θ1 in consideration of the strengths Ha and Hn.

### Second Example Embodiment

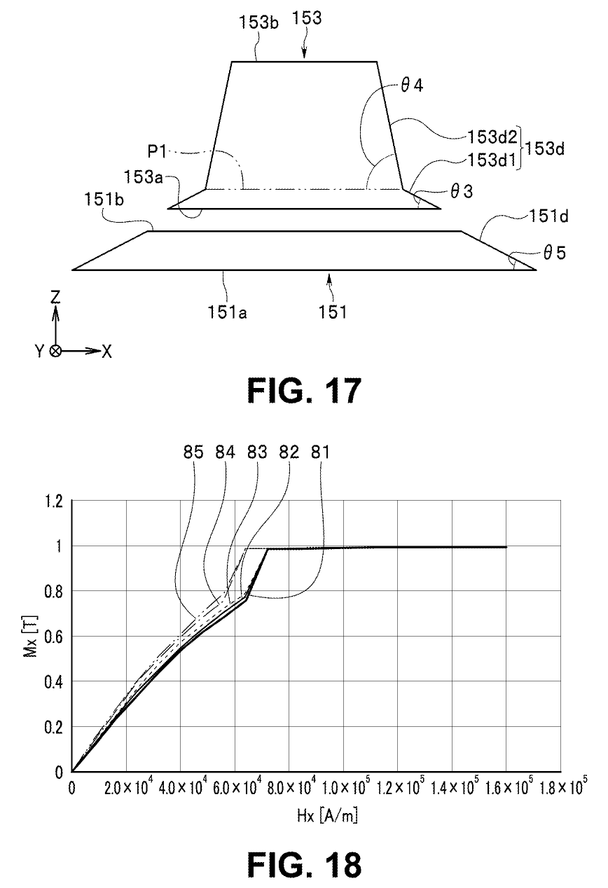

A second example embodiment of the disclosure will now be described. In the example embodiment, a magnetic sensor 1 includes MR elements 150 instead of the MR elements 50 in the first example embodiment. With reference to FIG. 16 and FIG. 17, a configuration of each MR element 150 will be described below. FIG. 16 is a side view showing the MR element 150. FIG. 17 is a side view showing a free layer and a magnetization pinned layer of the MR element 150.

The MR element 150 includes a magnetization pinned layer 151 having a magnetization whose direction is fixed, a free layer 153, a gap layer 152 arranged between the magnetization pinned layer 151 and the free layer 153, and a cap layer 154 arranged on the free layer 153. The configurations of the magnetization pinned layer 151, the gap layer 152, the free layer 153, and the cap layer 154 are the same as the respective configurations of the magnetization pinned layer 51, the gap layer 52, the free layer 53, and the cap layer 54 in the first example embodiment except for the shapes of the magnetization pinned layer 151 and the free layer 153 to be described below.

In the example embodiment, in particular, one part of the free layer 53 has a truncated cone shape or a substantially truncated cone shape, and the other part of the free layer 53 has a truncated cone shape or a substantially truncated cone shape different from that of the one part.

As shown in FIG. 17, the free layer 153 includes a lower surface 153a and an upper surface 153b located at respective both ends in a stacking direction of the magnetization pinned layer 151, the gap layer 152, and the free layer 153, and a side surface 153d connecting the lower surface 153a and the upper surface 153b. The lower surface 153a is located at the end in the −Z direction of the free layer 153 and faces the gap layer 152. The upper surface 153b is located at the end in the Z direction of the free layer 153 and faces the cap layer 154.

The side surface 153d includes a first portion 153d1 and a second portion 153d2 located between the first portion 153d1 and the upper surface 153b. At least one of the first portion 153d1 and the second portion 153d2 corresponds to an inclined portion inclined relative to a direction parallel to the stacking direction, i.e., the Z direction. When the first portion 153d1 corresponds to the inclined portion, the second portion 153d2 may also correspond to the inclined portion. Alternatively, when the first portion 153d1 corresponds to the inclined portion, the second portion 153d2 may not correspond to the inclined portion. In other words, the second portion 153d2 may not be inclined relative to the direction parallel to the Z direction. In the example embodiment, in particular, both the first portion 153d1 and the second portion 153d2 correspond to the inclined portion.

The planar shape of the side surface 153d when viewed in one direction parallel to the stacking direction, i.e., the Z direction, may be an annular shape. Each of the planar shape of the first portion 153d1 when viewed in the Z direction and the planar shape of the second portion 153d2 when viewed in the Z direction is an annular shape.

In FIG. 17, a sign θ3 indicates the angle of the first portion 153d1 of the side surface 153d with respect to the lower surface 153a of the free layer 153. The angle θ3 will be referred to as an inclination angle of the first portion 153d1 below. A sign θ4 indicates the angle of the second portion 153d2 of the side surface 153d with respect to the lower surface 153a of the free layer 153. The angle θ4 will be referred to as an inclination angle of the second portion 153d2 below. Note that, in FIG. 17, the inclination angle θ4 of the second portion 153d2 is expressed as the angle of the second portion 153d2 with respect to a virtual plane P1 parallel to the lower surface 153a of the free layer 153, for convenience. The inclination angle θ3 of the first portion 153d1 may be smaller than the inclination angle θ4 of the second portion 153d2.

The magnetization pinned layer 151 has a truncated cone shape or a substantially truncated cone shape. The magnetization pinned layer 151 includes a lower surface 151a and an upper surface 151b located at respective both ends in the direction parallel to the stacking direction, i.e., the Z direction, and a side surface 151d connecting the lower surface 151a and the upper surface 151b. The lower surface 151a is located at the end in the −Z direction of the magnetization pinned layer 151. The upper surface 151b is located at the end in the Z direction of the magnetization pinned layer 151 and faces the gap layer 152.

The side surface 151d includes an inclined portion inclined relative to the direction parallel to the stacking direction, i.e., the Z direction. In the example shown in FIG. 17, the entire side surface 151d is an inclined portion. In FIG. 17, a sign θ5 indicates an angle of the inclined portion of the side surface 151d with respect to the lower surface 151a of the magnetization pinned layer 151. The angle θ5 will be referred to as an inclination angle of the side surface 151d below.

In the example embodiment, the absolute value of the difference between the inclination angle θ3 of the first portion 153d1 and the inclination angle θ5 of the side surface 151d may be smaller than the absolute value of the difference between the inclination angle θ4 of the second portion 153d2 and the inclination angle θ5 of the side surface 151d. Note that the inclination angle θ5 of the side surface 151d may be the same or substantially same as the inclination angle θ3 of the first portion 153d1.

Next, a result of a third simulation for investigating influences of the inclination angle θ3 of the first portion 153d1 of the side surface 153d of the free layer 153 on the characteristics of the MR element 150 will be described. In the third simulation, the inclination angle θ3 was changed within a range from 5° to 30° while each of the diameter of the lower surface 153a of the free layer 153, the diameter of the upper surface 153b of the free layer 153, and the size of the free layer 153 in the direction parallel to the Z direction was maintained the same. In this state, the relationship between the strength Hx of the magnetic field component MFx and the magnitude Mx of the magnetization was determined for each value of the inclination angle θ3.

In the third simulation, the diameter of the lower surface 153a of the free layer 153 was set at 589 nm, the diameter of the upper surface 153b of the free layer 153 was set at 471 nm, and the size of the free layer 153 in the direction parallel to the Z direction was set at 50 nm. In the third simulation, the inclination angle θ4 of the second portion 153d2 of the side surface 153d was set at 60°.

In the third simulation, a relationship between the strength Hx of the magnetic field component MFx and the magnitude Mx of the magnetization was determined also for a case where the side surface 153d of the free layer 153 included only the second portion 153d2 without including the first portion 153d1. In this case, the shape of the free layer 153 is substantially that of the free layer 53 in the first example embodiment and has the same shape as the free layer 53 with the inclination angle θ1 of the side surface 53d being 60°.

From the relationship between the strength Hx of the magnetic field component MFx and the magnitude Mx of the magnetization, the ratio of the change amount of the magnitude Mx of the magnetization to the change amount of the strength Hx of the magnetic field component MFx, i.e., slope, was determined. Slope was determined within a range of the strength Hx of the magnetic field component MFx at which the free layer 153 would not be magnetically saturated.

From the relationship between the strength Hx of the magnetic field component MFx and the magnitude Mx of the magnetization, linearity of the magnitude Mx of the magnetization was determined. The linearity was determined within a range of the strength Hx of the magnetic field component MFx at which the free layer 153 would not be magnetically saturated.

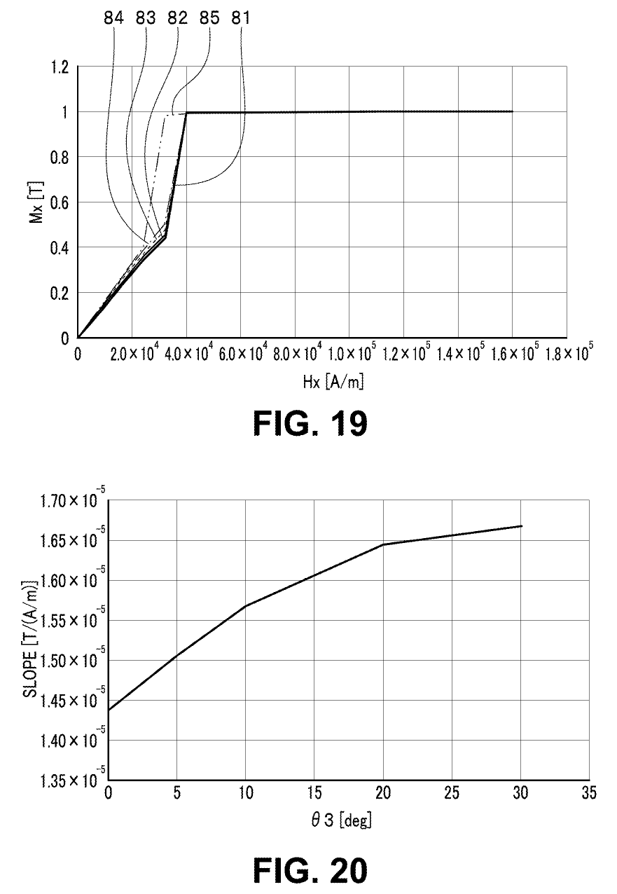

FIG. 18 and FIG. 19 are each a characteristic chart showing a relationship between the strength Hx of the magnetic field component MFx and the magnitude Mx of the magnetization. In FIG. 18 and FIG. 19, the horizontal axis represents the strength Hx, and the vertical axis represents the magnitude Mx of the magnetization. Note that, in FIG. 18 and FIG. 19, the unit of the strength Hx is assumed to be A/m, and the unit of the magnitude Mx of the magnetization is assumed to be T. FIG. 18 shows the relationship between the strength Hx and the magnitude Mx of the magnetization when the strength Hx is increased from 0 to magnetically saturate the free layer 153. FIG. 19 shows the relationship between the strength Hx and the magnitude Mx of the magnetization when the strength Hx is increased from 0 to magnetically saturate the free layer 153 and is thereafter decreased.

In FIG. 18 and FIG. 19, a reference numeral 81 indicates a case where the side surface 153d of the free layer 153 includes only the second portion 153d2 without including the first portion 153d1, a reference numeral 82 indicates a case where the inclination angle θ3 is 5°, a reference numeral 83 indicates a case where the inclination angle θ3 is 10°, a reference numeral 84 indicates a case where the inclination angle θ3 is 20°, and a reference numeral 85 indicates a case where the inclination angle θ3 is 30°.

FIG. 20 is a characteristic chart showing a relationship between the inclination angle θ3 and the slope. In FIG. 20, the horizontal axis represents the inclination angle θ3, and the vertical axis represents the slope. In FIG. 20, the slopes of respective values of the inclination angle θ3 are connected with a line. In FIG. 20, for the sake of convenience, the slopes of a case where the side surface 153d of the free layer 153 includes only the second portion 153d2 without including the first portion 153d1 (reference numeral 81 in FIG. 18 and FIG. 19) are plotted as slopes when the inclination angle θ3 is 0°. As shown in FIG. 20, the larger the inclination angle θ3 is, the larger the slope becomes.

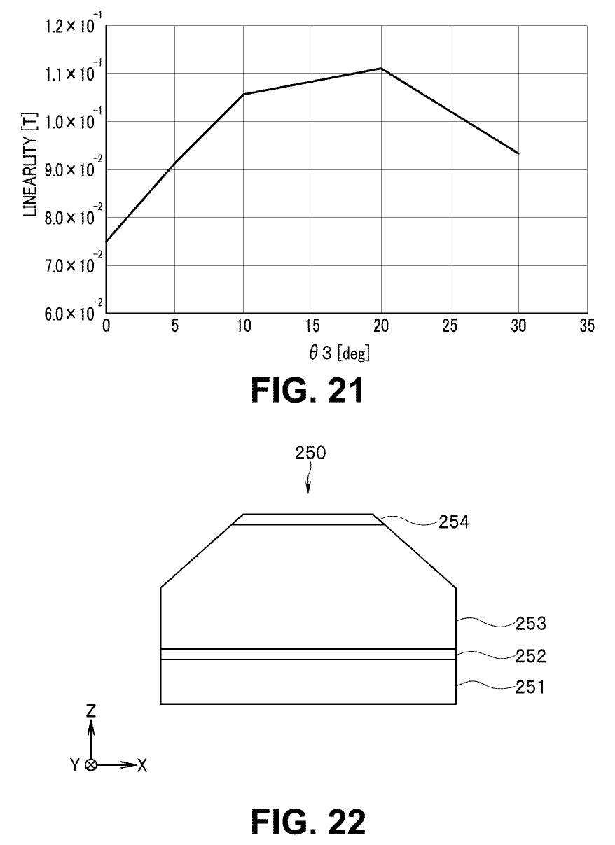

FIG. 21 is a characteristic chart showing a relationship between the inclination angle θ3 and linearity. In FIG. 21, the horizontal axis represents the inclination angle θ3, and the vertical axis represents the linearity. In FIG. 21, the values of the linearity at the respective values of the inclination angle θ3 are connected with a line. In FIG. 21, for the sake of convenience, the values of the linearity of a case where the side surface 153d of the free layer 153 includes only the second portion 153d2 without including the first portion 153d1 (reference numeral 81 in FIG. 18 and FIG. 19) are plotted as the values of the linearity when the inclination angle θ3 is 0°. As shown in FIG. 21, the larger the inclination angle θ3 is, the larger the value of the linearity becomes when the inclination angle θ3 is 0° or larger and 20° or smaller.

As understood from the result of the third simulation, by increasing the inclination angle θ3, the slope increases. In other words, according to the example embodiment, a simple configuration that the first portion 153d1 is provided to the side surface 153d of the free layer 153 can improve sensitivity of the MR element 150.

Note that, as shown in FIG. 21, the larger the inclination angle θ3 is, the larger the value of the linearity becomes when the inclination angle θ3 is 0° or larger and 20° or smaller. From a viewpoint of suppressing deterioration of the linearity of the MR element 150, it is desirable to determine the inclination angle θ3 in consideration of the value of the linearity.

The configuration, operations, and effects of the example embodiment are otherwise the same as those of the first example embodiment.

### Third Example Embodiment

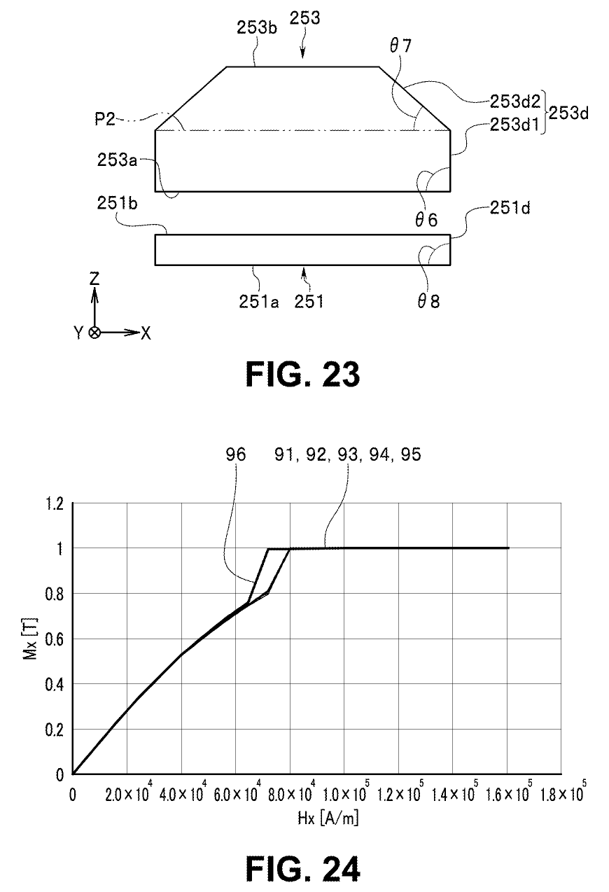

A third example embodiment of the disclosure will now be described. In the example embodiment, a magnetic sensor 1 includes MR elements 250 instead of the MR elements 50 in the first example embodiment. With reference to FIG. 22 and FIG. 23, a configuration of each MR element 250 will be described below. FIG. 22 is a side view showing the MR element 250. FIG. 23 is a side view showing a free layer and a magnetization pinned layer of the MR element 250.

The MR element 250 includes a magnetization pinned layer 251 having a magnetization whose direction is fixed, a free layer 253, a gap layer 252 arranged between the magnetization pinned layer 251 and the free layer 253, and a cap layer 254 arranged on the free layer 253. The configurations of the magnetization pinned layer 251, the gap layer 252, the free layer 253, and the cap layer 254 are the same as the respective configurations of the magnetization pinned layer 51, the gap layer 52, the free layer 53, and the cap layer 54 in the first example embodiment except for the shapes of the magnetization pinned layer 251 and the free layer 253 to be described below.

In the example embodiment, in particular, one part of the free layer 53 has a truncated cone shape or a substantially truncated cone shape, and the other part of the free layer 53 has a cylindrical shape or a substantially cylindrical shape.

As shown in FIG. 23, the free layer 253 includes a lower surface 253a and an upper surface 253b located at respective both ends in a stacking direction of the magnetization pinned layer 251, the gap layer 252, and the free layer 253, and a side surface 253d connecting the lower surface 253a and the upper surface 253b. The lower surface 253a is located at the end in the −Z direction of the free layer 253 and faces the gap layer 252. The upper surface 253b is located at the end in the Z direction of the free layer 253.

The side surface 253d includes a first portion 253d1 and a second portion 253d2 located between the first portion 253d1 and the upper surface 253b. At least one of the first portion 253d1 and the second portion 253d2 corresponds to an inclined portion inclined relative to a direction parallel to the stacking direction, i.e., the Z direction. When the second portion 253d2 corresponds to the inclined portion, the first portion 253d1 may not correspond to the inclined portion. In other words, the first portion 253d1 may not be inclined relative to the direction parallel to the Z direction. Alternatively, when the second portion 253d2 corresponds to the inclined portion, the first portion 253d1 may also correspond to the inclined portion. In the example embodiment, in particular, the second portion 253d2 corresponds to the inclined portion while the first portion 253d1 does not correspond to the inclined portion.

The planar shape of the side surface 253d when viewed in one direction parallel to the stacking direction, i.e., the Z direction, may be an annular shape. The planar shape of the second portion 253d2 when viewed in the Z direction may be an annular shape.

In FIG. 23, a sign θ6 indicates the angle of the first portion 253d1 of the side surface 253d with respect to the lower surface 253a of the free layer 253. The angle θ6 is 90° or substantially 90°. The angle θ6 will be referred to as an inclination angle of the first portion 253d1 below for convenience. A sign θ7 indicates the angle of the second portion 253d2 of the side surface 253d with respect to the lower surface 253a of the free layer 253. The angle θ7 will be referred to as an inclination angle of the second portion 253d2 below. Note that, in FIG. 23, the inclination angle θ7 of the second portion 253d2 is expressed as the angle of the second portion 253d2 with respect to a virtual plane P2 parallel to the lower surface 253a of the free layer 253, for convenience. The inclination angle θ7 of the second portion 153d2 may be smaller than the inclination angle θ6 of the first portion 153d1.

The magnetization pinned layer 251 has a cylindrical shape or a substantially cylindrical shape. The magnetization pinned layer 251 includes a lower surface 251a and an upper surface 251b located at respective both ends in the direction parallel to the stacking direction, i.e., the Z direction, and a side surface 251d connecting the lower surface 251a and the upper surface 251b. The lower surface 251a is located at the end in the −Z direction of the magnetization pinned layer 251. The upper surface 251b is located at the end in the Z direction of the magnetization pinned layer 251 and faces the gap layer 252.

In FIG. 23, a sign θ8 indicates the angle of the side surface 251d with respect to the lower surface 251a of the magnetization pinned layer 251. The angle θ8 is 90° or substantially 90°. The angle θ8 will be referred to as an inclination angle of the side surface 251d below for convenience.

In the example embodiment, the absolute value of the difference between the inclination angle θ6 of the first portion 253d1 and the inclination angle θ8 of the side surface 251d may be smaller than the absolute value of the difference between the inclination angle θ7 of the second portion 253d2 and the inclination angle θ8 of the side surface 251d. Note that the inclination angle θ8 of the side surface 251d may be the same or substantially same as the inclination angle θ6 of the first portion 253d1.

Next, a result of a fourth simulation for investigating influences of the inclination angle θ7 of the second portion 253d2 of the side surface 253d of the free layer 253 on the characteristics of the MR element 250 will be described. In the fourth simulation, the inclination angle θ7 was changed within a range from 40° to 90° while each of the diameter of the lower surface 253a of the free layer 253, the size of the first portion 253d1 of the side surface 253d in the direction parallel to the Z direction, and the size of the second portion 253d2 of the side surface 253d in the direction parallel to the Z direction was maintained the same. In this state, the relationship between the strength Hx of the magnetic field component MFx and the magnitude Mx of the magnetization was determined for each value of the inclination angle θ7. Note that, in a case where the inclination angle θ7 is 90°, the free layer 253 has a cylindrical or substantially cylindrical shape.

In the fourth simulation, the diameter of the lower surface 253a of the free layer 253 was set at 500 nm, the size of the first portion 253d1 of the side surface 253d in the direction parallel to the Z direction was set at 20 nm, and the size of the second portion 253d2 of the side surface 253d in the direction parallel to the Z direction was set at 30 nm.

From the relationship between the strength Hx of the magnetic field component MFx and the magnitude Mx of the magnetization, the ratio of the change amount of the magnitude Mx of the magnetization to the change amount of the strength Hx of the magnetic field component MFx, i.e., slope, was determined. Slope was determined within a range of the strength Hx of the magnetic field component MFx at which the free layer 253 would not be magnetically saturated.

From the relationship between the strength Hx of the magnetic field component MFx and the magnitude Mx of the magnetization, linearity of the magnitude Mx of the magnetization was determined. The linearity was determined within a range of the strength Hx of the magnetic field component MFx at which the free layer 253 would not be magnetically saturated.

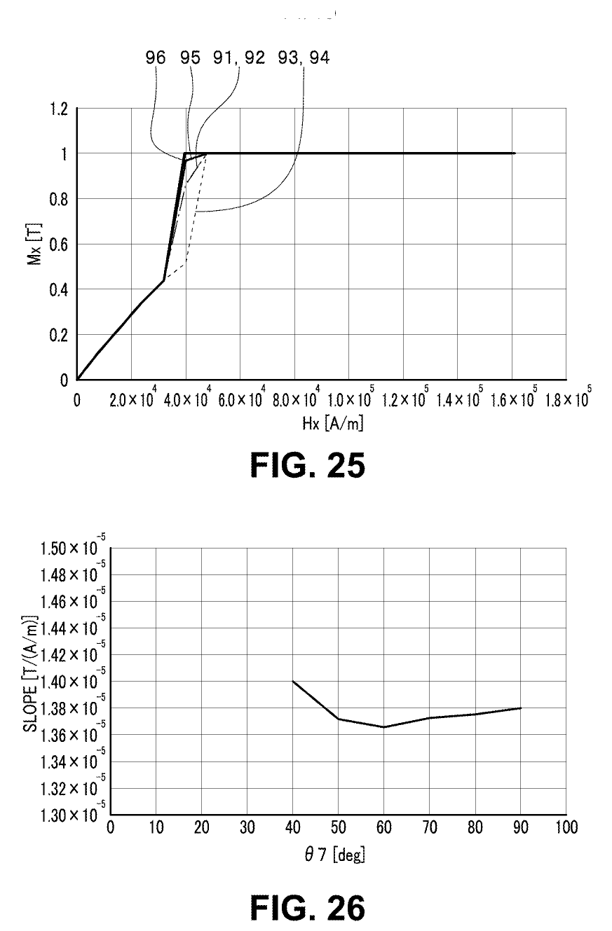

FIG. 24 and FIG. 25 are each a characteristic chart showing a relationship between the strength Hx of the magnetic field component MFx and the magnitude Mx of the magnetization. In FIG. 24 and FIG. 25, the horizontal axis represents the strength Hx, and the vertical axis represents the magnitude Mx of the magnetization. Note that, in FIG. 24 and FIG. 25, the unit of the strength Hx is A/m, and the unit of the magnitude Mx of the magnetization is T. FIG. 24 shows the relationship between the strength Hx and the magnitude Mx of the magnetization when the strength Hx is increased from 0 to magnetically saturate the free layer 253. FIG. 25 shows the relationship between the strength Hx and the magnitude Mx of the magnetization when the strength Hx is increased from 0 to magnetically saturate the free layer 253 and is thereafter decreased.

In FIG. 24 and FIG. 25, a reference numeral 91 indicates a case where the inclination angle θ7 is 90°, a reference numeral 92 indicates a case where the inclination angle θ7 is 80°, a reference numeral 93 indicates a case where the inclination angle θ7 is 70°, a reference numeral 94 indicates a case where the inclination angle θ7 is 60°, a reference numeral 95 indicates a case where the inclination angle θ7 is 50°, and a reference numeral 96 indicates a case where the inclination angle θ7 is 40°. In FIG. 24, except for the case where the angle θ7 is 40° (reference numeral 96), the curves representing the relationships between the strength Hx and the magnitude Mx of the magnetization at the respective values of the inclination angle θ7 overlap mostly. In FIG. 25, the curve of the case where the angle θ7 is 90° (reference numeral 91) and the curve of the case where the angle θ7 is 80° (reference numeral 92) overlap mostly. In FIG. 25, the curve of the case where the angle θ7 is 70° (reference numeral 93) and the curve of the case where the angle θ7 is 60° (reference numeral 94) overlap mostly.

FIG. 26 is a characteristic chart showing a relationship between the inclination angle θ7 and the slope. In FIG. 26, the horizontal axis represents the inclination angle θ7, and the vertical axis represents the slope. In FIG. 26, the slopes of respective values of the inclination angle θ7 are connected with a line. As shown in FIG. 26, the smaller the inclination angle θ7 is, the larger the slope becomes when the inclination angle θ7 is 30° or larger and 60° or smaller. The smaller the inclination angle θ7 is, the smaller the slope becomes when the inclination angle θ7 is 60 or larger and 90° or smaller.

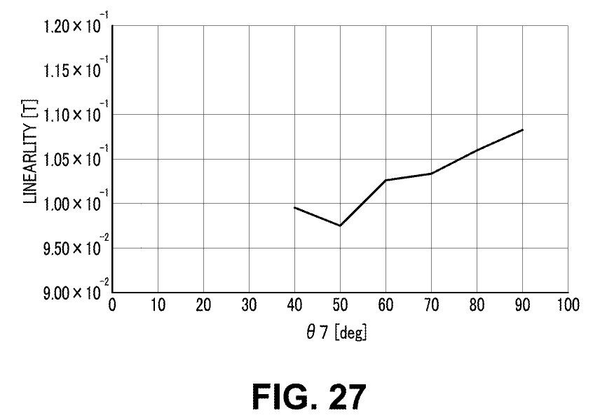

FIG. 27 is a characteristic chart showing a relationship between the inclination angle θ7 and linearity. In FIG. 27, the horizontal axis represents the inclination angle θ7, and the vertical axis represents the linearity. In FIG. 27, the values of the linearity at the respective values of the inclination angle θ7 are connected with a line. As shown in FIG. 27, the smaller the inclination angle θ7 is, the smaller the value of the linearity becomes when the inclination angle θ7 is 50° or larger and 90° or smaller.

As understood from the result of the fourth simulation, by reducing the inclination angle θ7, the value of the linearity decreases. In other words, according to the example embodiment, a simple configuration that the second portion 253d2 is provided to the side surface 253d of the free layer 253 can improve linearity.

Note that, as shown in FIG. 26, the smaller the inclination angle θ7 is, the smaller the slope becomes when the inclination angle θ7 is 60° or larger and 90° or smaller. From a viewpoint of suppressing deterioration of the sensitivity of the MR element 250, it is desirable to determine the inclination angle θ7 in consideration of the slope.

The configuration, operations, and effects of the example embodiment are otherwise the same as those of the first example embodiment.

Note that the disclosure is not limited to each of the foregoing example embodiments, and various modifications may be made thereto. For example, the shape of the side surface 53d of the free layer 53 of the MR element 50 is not limited to the examples described in the example embodiments. For example, the side surface 53d of the free layer 53 may include three or more portions having different inclination angles.

As described above, a magnetoresistive element according to one embodiment of the disclosure includes a magnetization pinned layer having a magnetization whose direction is fixed, a free layer configured to be able to have a magnetic vortex structure and so that a center of the magnetic vortex structure can move in accordance with a target magnetic field, and a gap layer arranged between the magnetization pinned layer and the free layer. The free layer includes a first lower surface located at one end in a stacking direction of the magnetization pinned layer, the gap layer and the free layer, a first upper surface located at the other end in the stacking direction, and a first side surface connecting the first lower surface and the first upper surface. The first side surface includes an inclined portion inclined relative to the stacking direction.

In the magnetoresistive element according to one embodiment of the disclosure, the first side surface may include a first portion and a second portion located between the first portion and the first upper surface. One of the first portion and the second portion may be the inclined portion.

In the magnetoresistive element according to one embodiment of the disclosure, the first portion may be the inclined portion. The angle of the first portion with respect to the first lower surface may be smaller than an angle of the second portion with respect to the first lower surface.

In the magnetoresistive element according to one embodiment of the disclosure, the second portion may be the inclined portion. The angle of the second portion with respect to the first lower surface may be smaller than an angle of the first portion with respect to the first lower surface. The first portion may be inclined relative to the stacking direction.

In the magnetoresistive element according to one embodiment of the disclosure, the magnetization pinned layer may include a second lower surface located at one end in the stacking direction, a second upper surface located at the other end in the stacking direction, and a second side surface connecting the second lower surface and the second upper surface. The second side surface may include a third portion inclined relative to the stacking direction. The first side surface may include a first portion and a second portion located between the first portion and the first upper surface. The first portion may be the inclined portion. When an angle of the first portion with respect to the first lower surface is assumed to be a first angle, an angle of the second portion with respect to the first lower surface is assumed to be a second angle, and an angle of the third portion with respect to the second lower surface is assumed to be a third angle, an absolute value of a difference between the first angle and the third angle may be smaller than an absolute value of a difference between the second angle and the third angle.

In the magnetoresistive element according to one embodiment of the disclosure, a planar shape of the inclined portion when viewed in the stacking direction may be an annular shape.

A magnetic sensor according to one embodiment of the disclosure is a magnetic sensor including a plurality of magnetic detection elements. Each of the plurality of magnetic detection elements is the magnetoresistive element according to one embodiment of the disclosure.

In the magnetoresistive element of the disclosure, the first side surface of the free layer includes an inclined portion inclined relative to the stacking direction. With this, according to the disclosure, a magnetoresistive element and a magnetic sensor capable of improving sensitivity and linearity can be provided.

Obviously, various aspects and modification examples of the disclosure can be practiced in the light of the foregoing descriptions. Thus, within the scope of the appended claims and equivalents thereof, the disclosure can be practiced in embodiments other than the foregoing example embodiments.

1. A magnetoresistive element comprising:
located at one end in a stacking direction of the magnetization pinned layer, the gap layer and the free layer, a first upper surface located at the other end in the stacking direction, and a first side surface connecting the first lower surface and the first upper surface, and

2. The magnetoresistive element according to claim 1, wherein

3. The magnetoresistive element according to claim 2, wherein

4. The magnetoresistive element according to claim 2, wherein

5. The magnetoresistive element according to claim 4, wherein the first portion is inclined relative to the stacking direction.

6. The magnetoresistive element according to claim 1, wherein
located at one end in the stacking direction, a second upper surface located at the other end in the stacking direction, and a second side surface connecting the second lower surface and the second upper surface, and

7. The magnetoresistive element according to claim 6, wherein

8. The magnetoresistive element according to claim 1, wherein a planar shape of the inclined portion when viewed in the stacking direction is an annular shape.

9. A magnetic sensor comprising a plurality of magnetic detection elements, wherein
